(19) United States
(12) Patent Application Publication
(10) Pub. No.: US 2026/0282955 A1
(43) Pub. Date: Sep. 17, 2026

(54) SEMICONDUCTOR PACKAGE AND METHOD OF MANUFACTURING THE SAME

(71) Applicant: Samsung Electronics Co., Ltd., Suwon-si (KR)

(72) Inventors: Wonjae Lee, Suwon-si (KR); Heeyoub Kang, Suwon-si (KR); Chanhee Kim, Suwon-si (KR); Eunkyeong Park, Suwon-si (KR); Sungoh Ahn, Suwon-si (KR); Seokbeom Yong, Suwon-si (KR)

(21) Appl. No.: 19/398,775

(22) Filed: Nov. 24, 2025

(30) Foreign Application Priority Data
Mar. 11, 2025 (KR) 10-2025-0031449

(51) Int. Cl. H10W 70/60; H10W 70/63; H10W 70/65; H10W 72/00

(52) U.S. Cl. CPC H10W 70/618; H10W 70/635; H10W 70/65; H10W 72/823

(57) ABSTRACT

A semiconductor package includes a bridge die; an encapsulant; a redistribution structure including redistribution patterns and an upper insulating layer; semiconductor chips disposed on the redistribution structure and electrically connected to the redistribution patterns; connection posts extending in a vertical direction in the encapsulant and electrically connected to the redistribution patterns; and a plurality of connection conductor structures below the bridge die and the connection posts, wherein the plurality of connection conductor structures include a first group of the plurality of connection conductor structures overlapping the bridge die, and a second group of the plurality of connection conductor structures overlapping the connection posts, wherein each of the first group of the plurality of connection conductor structures includes a connection pad; an upper connection solder in contact with and electrically connected to the bridge die on the connection pad; and a lower connection solder below the connection pad.

### CROSS-REFERENCE TO RELATED APPLICATION(S)

This application claims benefit of priority to Korean Patent Application No. 10-2025-0031449 filed on Mar. 11, 2025, in the Korean Intellectual Property Office, the disclosure of which is incorporated herein by reference in its entirety.

### BACKGROUND

With development of the electronics industry and user demand, an electronic device has been designed to have a reduced size and weight, and a semiconductor package used in an electronic device has been desired to have a reduced size and weight with higher performance and greater capacity. To implement higher performance and greater capacity along with a reduced size and weight, research and development on a semiconductor package structure has been conducted including an interposer interconnecting a plurality of semiconductor chips.

### SUMMARY

In some implementations of the present disclosure is to provide a semiconductor package having improved integration density and electrical properties.

In some implementations of the present disclosure is to provide a method of manufacturing a semiconductor package having improved integration density, electrical properties, and process stability.

According to example implementations of the present disclosure, a semiconductor package includes a bridge die; an encapsulant surrounding the bridge die; a redistribution structure disposed on the encapsulant and including redistribution patterns electrically connected to the bridge die and an upper insulating layer surrounding the redistribution patterns; semiconductor chips disposed on the redistribution structure and electrically connected to the redistribution

patterns; connection posts extending in a vertical direction in the encapsulant and electrically connected to the redistribution patterns; and a plurality of connection conductor structures disposed below the bridge die and the connection posts, wherein the plurality of connection conductor structures include a first group of the plurality of connection conductor structures overlapping the bridge die, and a second group of the plurality of connection conductor overlapping the connection posts, wherein each of the first group of the plurality of connection conductor structures includes a connection pad; an upper connection solder in contact with and electrically connected to the bridge die on the connection pad; and a lower connection solder below the connection pad.

According to example implementations of the present disclosure, a semiconductor package includes a bridge die including a bridge body, through-vias penetrating the bridge body, a bridge redistribution structure on the bridge body, a lower bridge insulating layer covering a lower surface of the bridge body, and lower bridge pads disposed below the lower bridge insulating layer and electrically connected to the through-vias; an encapsulant surrounding the bridge die; a redistribution structure disposed on the encapsulant and including an upper insulating layer and redistribution patterns in the upper insulating layer; and connection conductor structures electrically connected to the lower bridge pads below the bridge die, wherein the bridge redistribution structure includes an upper bridge insulating layer; upper bridge pads on the upper bridge insulating layer and electrically connected to the redistribution patterns; and bridge redistribution layers electrically connecting the through-vias to the upper bridge pads in the upper bridge insulating layer, wherein the encapsulant covers at least a portion of each of an upper surface of the upper bridge insulating layer, a lower surface of the lower bridge insulating layer, side surfaces of the upper bridge pads and side surfaces of the lower bridge pads.

According to example implementations of the present disclosure, a semiconductor package includes an encapsulant; a redistribution structure disposed on the encapsulant, and including an upper insulating layer and redistribution patterns in the upper insulating layer; semiconductor chips disposed on the redistribution structure, and electrically connected to the redistribution patterns; a bridge die disposed in the encapsulant, and electrically connected to the semiconductor chips through the redistribution patterns; connection posts spaced apart from the bridge die in a horizontal direction in the encapsulant, extending in a vertical direction, and electrically connected to the redistribution patterns; a first group of the plurality of connection pads electrically connected to the bridge die below the bridge die; and lower connection solders disposed below lower surfaces of a first group of the plurality of connection pads, and wherein the lower surfaces of a first group of the plurality of connection pads are coplanar with a lower surface of the encapsulant.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor package according to example implementations of the present disclosure;

FIG. 2 is a cross-sectional diagram illustrating a semiconductor package according to example implementations of the present disclosure;

FIG. 3 is an enlarged diagram illustrating a portion of a semiconductor package according to example implementations of the present disclosure;

FIGS. 4 and 5 are enlarged diagrams illustrating a portion of a semiconductor package according to example implementations of the present disclosure;

FIG. 6 is a cross-sectional diagram illustrating a semiconductor package according to example implementations of the present disclosure;

FIG. 7 is a plan diagram illustrating a semiconductor package according to example implementations of the present disclosure;

FIGS. 8, 9, 10, 11, 12, 13, and 14, are cross-sectional diagrams illustrating processes of a method of manufacturing a semiconductor package in order according to example implementations of the present disclosure; and

FIG. 15 is a cross-sectional diagram illustrating a method of manufacturing a semiconductor package according to example implementations of the present disclosure.

### DETAILED DESCRIPTION

Hereinafter, implementations of the present disclosure will be described as below with reference to the accompanying drawings.

In example implementations, the terms such as “upper,” “upper portion,” “upper surface,” “lower,” “lower portion,” “lower surface,” “side surface,” or the like, may be referred to based on the drawings unless otherwise indicated.

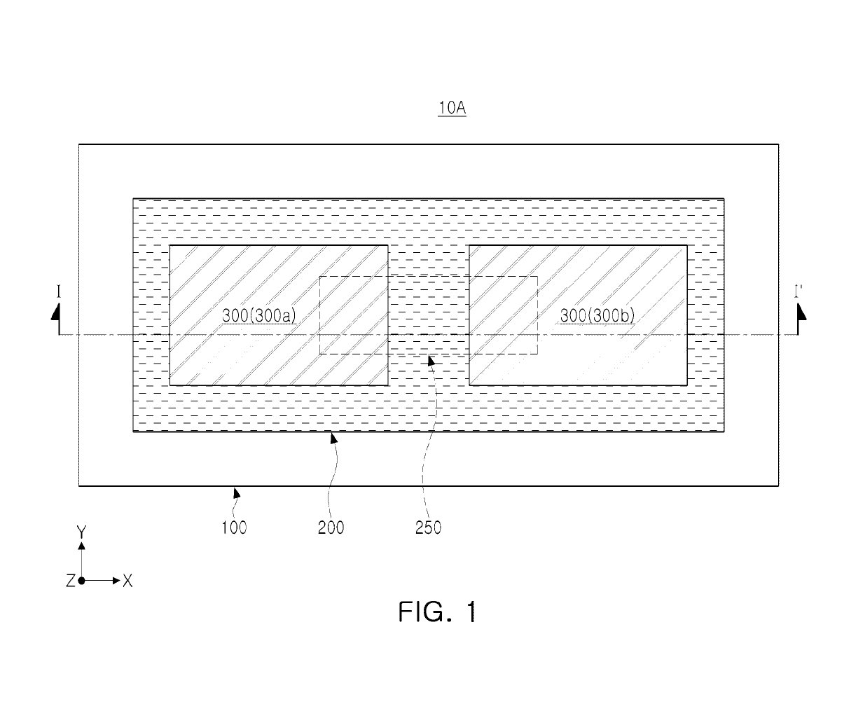

FIG. 1 is a plan diagram illustrating a semiconductor package according to example implementations. For ease of description, FIG. 1 illustrates only a portion of elements of the semiconductor package.

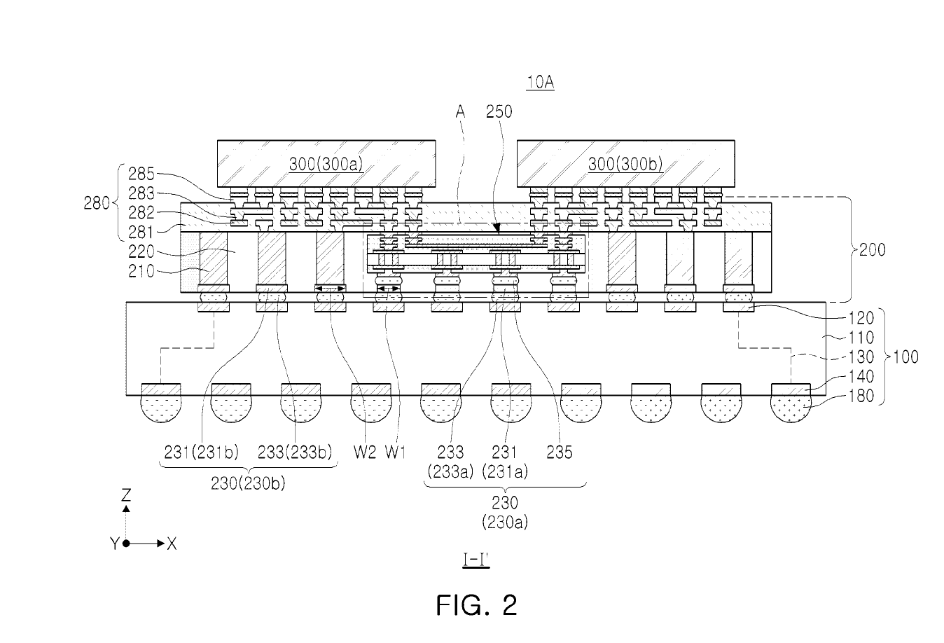

FIG. 2 is a cross-sectional diagram illustrating a semiconductor package according to example implementations, illustrating a cross-sectional surface of the semiconductor package in FIG. 1 taken along line I-I’.

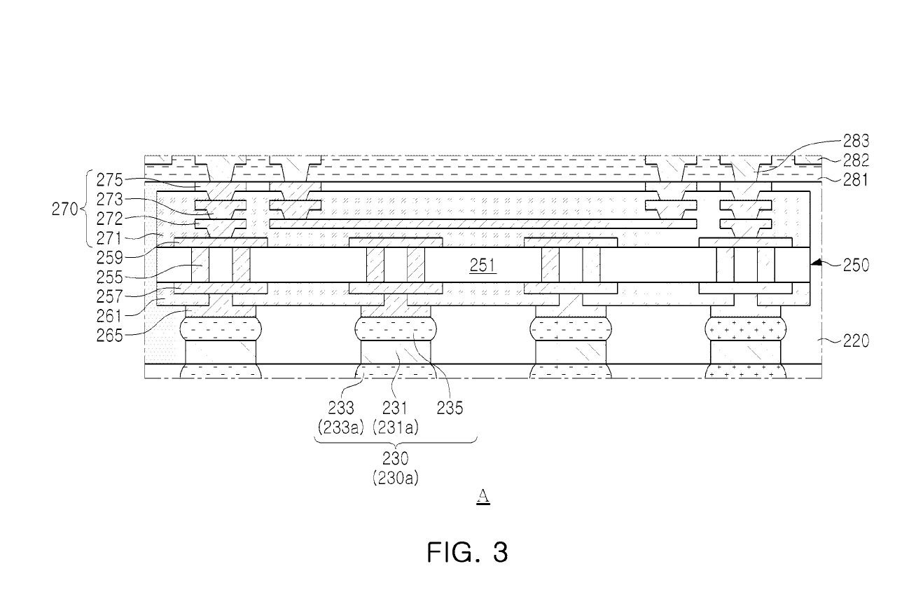

FIG. 3 is an enlarged diagram illustrating a portion of a semiconductor package according to example implementations, illustrating region ‘A’ in FIG. 2.

Referring to FIGS. 1-3, the semiconductor package 10A may include a package substrate 100, an interposer substrate 200, and semiconductor chips 300.

The package substrate 100 may be configured as a support substrate on which the interposer substrate 200 and the semiconductor chips 300 are mounted, and may be configured as a semiconductor package substrate including a printed circuit board (PCB), a ceramic substrate, a glass substrate, a tape interconnection substrate, or the like. The package substrate 100 may include

a substrate body 110, upper package pads 120, lower package pads 140, an interconnection circuit 130 electrically connecting the upper package pads 120 to the lower package pads 140, and external connection terminals 180.

The substrate body 110 may include different materials depending on the type thereof. For example, when the package substrate 100 is configured as a printed circuit board, an interconnection layer may be further stacked on one surface or both surfaces of a body copper-clad laminate or copper-clad laminate. The substrate body 110 may include an insulating material which electrically and physically protects the interconnection circuit 130, such as a thermosetting resin such as an epoxy resin, a thermoplastic resin such as a polyimide, or a prepreg including an inorganic filler or/and glass fiber, glass cloth, or glass fabric, Ajinomoto build-up film (ABF), frame retardant 4 (FR4), or the like.

The upper package pads 120, the lower package pads 140, and the interconnection circuit 130 may form an electrical path connecting a lower surface to an upper surface of the package substrate 100. The interconnection circuit 130 may include at least one metal from among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C), or an alloy of two or more metals.

External connection terminals 160 connected to the lower package pads 140 may be disposed on a lower surface of the substrate body 110. The external connection terminals 160 may include, for example, solder balls. The solder balls may include tin (Sn), bismuth (Bi), lead (Pb), silver (Ag), or alloys thereof.

The interposer substrate 200 may be disposed on the package substrate 100. The interposer substrate 200 may be configured as a support substrate on which semiconductor chips 300 are mounted, and may be disposed between the package substrate 100 and the semiconductor chips 300. The interposer substrate 200 may include a bridge die 250, connection posts 210, an encapsulant 220, connection conductor structures 230, and a redistribution structure 280.

The interposer substrate 200 in the example implementations may include a redistribution structure 280 disposed in an upper portion of the encapsulant 220, and a redistribution structure may not be disposed in a lower portion of the encapsulant 220. As the redistribution structure of the lower portion is not provided, a semiconductor package having improved integration density may be provided. The interposer substrate 200 in the example implementation may include a bridge die 250 electrically connected to a plurality of semiconductor chips 330 and a plurality of connection conductor structures 230. Signal transfer between the semiconductor chips 300 may be performed through a redistribution structure 280 disposed in an upper portion of the encapsulant 220 and a bridge redistribution structure 270 of the bridge die 250. Transfer of power or ground connected to the semiconductor chips 300 may be transferred through the redistribution structure 280, the connection posts 210 and a second group of connection conductor structures 230b, or through the redistribution structure 280, the bridge die 250 and a first group of connection conductor structures 230a. Since the redistribution structure in a lower portion of the encapsulant 220 is not provided, a power or ground path may be shortened, thereby providing a semiconductor package having electrical properties and having improved connection reliability. In some implementations, the semiconductor package may include connection conductor structures 230 disposed in a lower portion of the encapsulant 220, such that during the manufacturing process exposure of the bridge die 250 to a lower end of the encapsulant 220 may be reduced or the bridge die 250 may not be exposed during the process, such that reliability may be improved during the process.

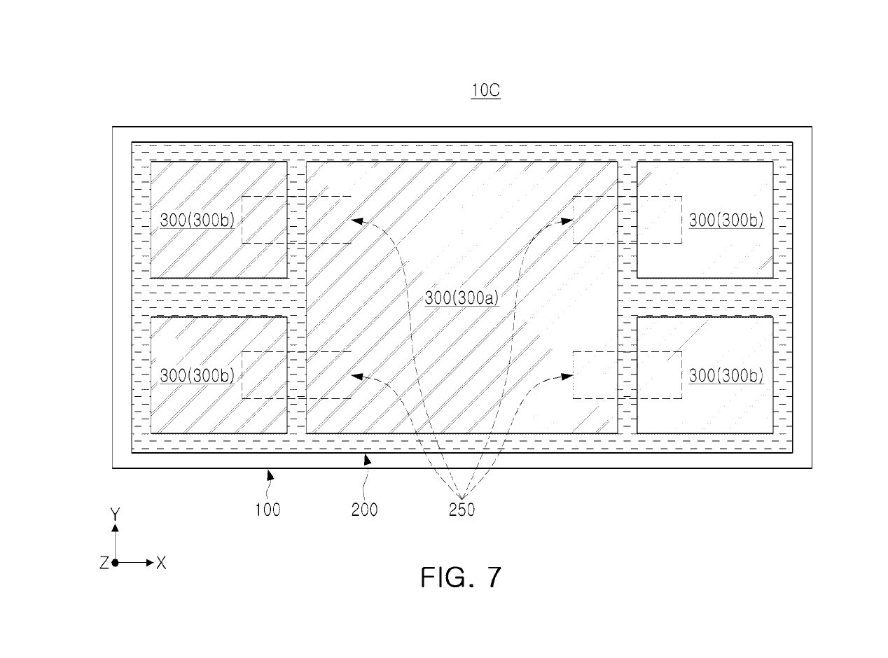

The bridge die 250 may be disposed in the encapsulant 220. The bridge die 250 may be electrically connected to the semiconductor chips 300 through the redistribution structure 280, and may be electrically connected to the package substrate 100 through the first group of connection conductor structures 230a. That is, the bridge die 250 may provide a path for electrically connecting the semiconductor chips 300 disposed in an upper partial region of the semiconductor package 10A, and may provide a path for electrically connecting the semiconductor chips 300 to the package substrate 100. The bridge die 250 may transfer complex signal lines of the semiconductor chips 300 to each other and may provide a path for power or ground transferred to the semiconductor chips 300. The bridge die 250 may include a portion vertically overlapping the first semiconductor chip 300A and the second semiconductor chip 300b. In some implementations, the number of the bridge dies 250 may be greater than the illustrated example (see FIG. 7). The bridge die 250 may include a bridge body 251, through-vias 255, lower body pads 257, upper body pads 259, a lower bridge insulating layer 261, lower bridge pads 265, and a bridge redistribution structure 270.

The bridge body 251 may be a silicon (Si) body. The bridge body 251 may include a semiconductor element such as silicon, germanium, or a compound semiconductor such as silicon carbide (SiC), gallium arsenide (GaAs), indium arsenide (InAs), and indium phosphide (InP). The bridge body 251 may include an insulating film disposed on an upper surface and a lower surface.

The through-vias 255 may be through-silicon vias (TSVs) penetrating the bridge body 251 in a vertical direction (e.g., Z-direction). The through-vias 255 may provide an electrical path connecting the lower body pad 257 and the lower bridge pad 265 to the upper body pad 259 and the bridge redistribution layers 272. Upper surfaces of the through-vias 255 may be in contact with the upper body pads 259, and a lower surface of the through-vias 255 may be in contact with the lower body pads 257. The through-vias 255 may include a conductive plug and a barrier film surrounding the conductive plug. The conductive plug may include a metal material, for example, tungsten (W), titanium (Ti), aluminum (Al), or copper (Cu). The conductive plug may be formed by a plating process, a PVD process, or a CVD process. The barrier film may include an insulating barrier film and/or a conductive barrier film. The insulating barrier film may include an oxide film, a nitride film, a carbide film, a polymer, or a combination thereof. The conductive barrier film may include a metal compound, for example, tungsten nitride (WN), titanium nitride (TiN), or tantalum nitride (TaN). The barrier film may be formed by a PVD process or a CVD process.

The lower body pads 257 may be electrically connected to the through-vias 255 on a lower surface of the bridge body 251. An upper surface of the lower body pad 257 may be in contact with a lower surface of through-via 255 and a lower surface of bridge body 251. The lower body pad 257 may be in contact with an insulating film disposed on a lower surface of bridge body 251. The lower body pad 257 may be electrically connected to the lower bridge pad 265. A side surface of the lower body pad 257 may be covered by a lower bridge insulating layer 261. A portion of a lower surface of the lower body pad 257 may be in contact with the lower bridge pad 265, and the other portion may be in contact with the lower bridge insulating layer 261. Depending on description, the lower body pads 257 may also be described as being included in the lower bridge pads 265. The lower body pads 257 may include a conductive material. The lower body pads 257 may include a metal, for example, copper (Cu), aluminum (Al), silver (Ag), tin (Sn), gold (Au), nickel (Ni), lead (Pb), titanium (Ti), or an alloy thereof.

The upper body pads 259 may be electrically connected to the through-vias 255 on an upper surface of the bridge body 251. The upper surface of the upper body pad 259 may be in contact with an upper surface of the through-via 255 and an upper surface of the bridge body 251. The upper body pad 259 may be in contact with an insulating film disposed on the upper surface of the bridge body 251. The upper body pads 259 may be electrically connected to bridge redistribution layers 272 of the bridge redistribution structure 270. The upper body pad 259 may be in contact with and connected to the bridge redistribution via 273 of the bridge redistribution structure 270. A side surface of the upper body pad 259 may be covered by an upper bridge insulating layer 271. A portion of the upper surface of the upper body pad 259 may be in contact with the bridge redistribution via 273, and the other portion may be in contact with the upper bridge insulating layer 271. Depending on description, the upper body pads 259 may be described as being included in the bridge redistribution structure 270. The upper body pads 259 may include a conductive material. For example, the upper body pads 259 may include a metal including copper (Cu), aluminum (Al), silver (Ag), tin (Sn), gold (Au), nickel (Ni), lead (Pb), titanium (Ti), or an alloy thereof.

In some implementations, a pair of a lower portion body pad 257 and an upper body pad 259 overlapping each other in a vertical direction may be connected to two through-vias 255, but an example implementation thereof is not limited thereto. In an example implementation, differently from the illustrated example, a pair of a lower portion body pad 257 and an upper body pad 259 may be connected to a single through-via 255, or may be connected to a greater number of the through-vias 255.

A lower bridge insulating layer 261 may cover a lower surface of a bridge body 251. The lower surface of the lower bridge insulating layer 261 may be defined as a lower surface of the bridge die 250. The lower bridge insulating layer 261 may include an insulating material electrically and physically protecting the bridge body 251. For example, the lower bridge insulating layer 261 may include a thermosetting resin such as an epoxy resin, a thermoplastic resin such as a polyimide, or a prepreg including inorganic fillers and/or glass fibers (glass cloth, glass fabric), Ajinomoto build-up film (ABF), frame retardant 4 (FR4), or the like.

The lower bridge pads 265 may be disposed below a lower surface of the lower bridge insulating layer 261. The lower bridge pads 265 may include a pad portion disposed below a lower surface of the lower bridge insulating layer 261 and a connection portion penetrating the lower bridge insulating layer 261 and connected to the lower body pads 257. The lower bridge pads 265 may be in contact with the first group of the first group of connection conductor structures 230a. A lower surface of the lower bridge pads 265 may be defined as a lower end of the bridge die 250. A lower surface of the lower bridge pad 265, which is a lower end of the bridge die 250, may be positioned at a level higher than a level of a lower surface of the connection post 210. The lower bridge pads 265 may include a conductive material. For example, the lower bridge pads 265 may include a metal including copper (Cu), aluminum (Al), silver (Ag), tin (Sn), gold (Au), nickel (Ni), lead (Pb), titanium (Ti), or an alloy thereof.

The bridge redistribution structure 270 may be disposed on an upper surface of the bridge body 251. The bridge redistribution structure 270 may interconnect complex signal lines between the semiconductor chips 300. The bridge redistribution structure 270 may transfer power supplied to the semiconductor chips 300. The bridge redistribution structure 270 may include an upper bridge insulating layer 271, bridge redistribution layers 272, bridge redistribution vias 273, and upper bridge pads 275.

The bridge redistribution layers 272, the bridge redistribution vias 273, and the upper bridge pads 275 may be collectively referred to as bridge redistribution patterns 272, 273, and 275. The number of the bridge redistribution patterns 272, 273, and 275 may be greater or less than the example illustrated in the drawing. The bridge redistribution patterns 272, 273, and 275 may perform various functions depending on a design. For example, the bridge redistribution patterns 272, 273, and 275 may include a ground (GrouND: GND) pattern, a power (PoWeR: PWR) pattern, and a signal (Signal: S) pattern. Here, the signal (S) pattern may be defined as a transmission path of various signals, such as a data signal, other than the ground (GND) pattern, power(PWR) pattern, or the like. The signal (S) pattern may be a pattern for interconnecting complex signal lines between the semiconductor chips 300. The ground (GrouND: GND) pattern, power (PoWeR: PWR) pattern may be electrically connected to the first group of connection conductor structures 230a through the through-vias 255.

The upper bridge insulating layer 271 may cover the upper surface of the bridge body 251. The upper surface of the upper bridge insulating layer 271 may be defined as the upper surface of the bridge die 250. In some implementations, the upper bridge insulating layer 271 may be spaced apart from the upper insulating layer 281. The upper bridge insulating layer 271 may include an insulating material for electrically and physically protecting the bridge body 251. For example, the upper bridge insulating layer 271 may include a thermosetting resin such as an epoxy resin, a thermoplastic resin such as a polyimide, or a prepreg including inorganic fillers and/or glass fibers (glass cloth, glass fabric), Ajinomoto build-up film (ABF), frame retardant 4 (FR4), or the like.

The bridge redistribution layers 272 may be disposed in the upper bridge insulating layer 271. The number of the bridge redistribution layers 272 may be greater or less than the example illustrated in the drawing. The bridge redistribution layers 272 may be disposed in more or fewer layers than the example illustrated in the drawing. For example, the bridge redistribution layers 272 may be disposed in three or more, five or fewer layers, but example implementations thereof are not limited thereto. The bridge redistribution layers 272 may include a conductive material, for example, a metal including copper (Cu), aluminum (Al), silver (Ag), tin (Sn), gold (Au), nickel (Ni), lead (Pb), titanium (Ti), or an alloy thereof.

The bridge redistribution vias 273 may extend into a partial region of the upper bridge insulating layer 271 and may be electrically connected to the bridge redistribution layers 272. For example, the bridge redistribution vias 273 may interconnect bridge redistribution layers 272 disposed on different levels. A portion of the bridge redistribution vias 273 may interconnect the upper bridge pads 275 to the bridge redistribution layers 272. A portion of the bridge redistribution vias 273 may interconnect the bridge redistribution layers 272 to the upper body pads 259. The bridge redistribution vias 273 may include a conductive material, for example, a metal including copper (Cu), aluminum (Al), silver (Ag), tin (Sn), gold (Au), nickel (Ni), lead (Pb), titanium (Ti), or alloys thereof. The bridge redistribution vias 273 may be filled vias in which a metal material is filled in a via hole or conformal vias in which a metal material extends along an inner wall of a via hole.

The upper bridge pads 275 may be disposed on the upper bridge insulating layer 271. A side surface of the upper bridge pad 275 may be covered by an encapsulant 220. The upper surface of the upper bridge pad 275 may be in contact with a redistribution structure 280. The upper surface of the upper bridge pad 275 may be in contact with the upper insulating layer 281. The upper surface of the upper bridge pad 275 may be defined as an upper end of the bridge die 250. The upper surface of the upper bridge pad 275, which is an upper end of the bridge die 250, may be positioned at the same level as the upper surfaces of the connection posts 210. The upper bridge pads 275 may be electrically connected to redistribution patterns 282, 283, and 285 of the redistribution structure 280. A portion of the upper surface of the upper bridge pads 275 may be in contact with the redistribution via 283, and the other portion may be in contact with the upper insulating layer 281. The upper bridge pads 275 may include a conductive material, for example, a metal including copper (Cu), aluminum (Al), silver (Ag), tin (Sn), gold (Au), nickel (Ni), lead (Pb), titanium (Ti), or an alloy thereof.

The connection posts 210 may extend into the encapsulant 220 and may electrically connect the redistribution patterns 282, 283, and 285 to the second group of connection conductor structures 230b. The connection posts 210 may extend in a vertical direction (e.g., in the Z direction) in the encapsulant 220. The connection posts 210 may be disposed around the bridge die 250 in the encapsulant 220, and may be disposed to surround the bridge die 250. The connection posts 210 may include a conductive material, for example, copper (Cu). In some implementations, a metal seed layer (not illustrated) including titanium (Ti), copper (Cu), or the like, may be formed on a lower surface of the connection posts 210.

The encapsulant 220 may surround the bridge die 250 and the connection posts 210. The encapsulant 220 may be disposed below the redistribution structure 280 and may surround at least a portion of each of the bridge die 250, the connection posts 210 and the connection conductor structures 230. The encapsulant 220 may cover at least a portion of each of an upper surface and a lower surface and also a side surface of the bridge die 250. The encapsulant 220 may fill a space between the bridge die 250 and the redistribution structure 280. The encapsulant 220 may surround side surfaces of the connection pads 231 and side surfaces of the upper connection solders 235. The encapsulant 220 may cover at least a portion of each of an upper surface of the upper bridge insulating layer 271, a lower surface of the lower bridge insulating layer 261, side surfaces of the upper bridge pads 275 and side surfaces of the lower bridge pads 265. The encapsulant 220 may be in contact with at least a portion of each of the upper surface of the upper bridge insulating layer 271, a lower surface of the lower bridge insulating layer 261, side surfaces of the upper bridge pads 275 and side surfaces of the lower bridge pads 265. The encapsulant 220 may include, for example, a thermosetting resin such as an epoxy resin, a thermoplastic resin such as a polyimide, or a prepreg, ABF, FR-4, BT, epoxy molding compound (EMC). The encapsulant 220 may include an underfill layer disposed below the bridge die 250. The underfill layer may have a capillary underfill (CUF) structure, but example implementations thereof are not limited thereto. The underfill layer may also have a molded underfill (MUF) structure integrated with the encapsulant 220.

Connection conductor structures 230 may be disposed on a lower surface of the encapsulant 220. The interposer substrate 200 may be connected to the package substrate 100 through the connection conductor structures 230. The connection conductor structures 230 may include a first group of connection conductor structures 230a, connected to the bridge die 250, and a second group of connection conductor structures 230b, connected to the connection posts 210. The first group of connection conductor structures 230a may overlap the bridge die 250 in a vertical direction, and the second group of the connection conductor structures 230b may overlap the connection posts 210 in a vertical direction. A portion of the first group of connection conductor structures 230a may overlap the semiconductor chips 300 in a vertical direction. Each of the connection conductor structures 230 may include a connection pad 231 and a lower connection solder 233. The first group of connection conductor structure 230a may include a first group of the first group of the connection pad 231a and a first group of the lower connection solder 233a. The second group of connection conductor structure 230b may include a second group of a connection pad 231b and a second group of a lower connection solder 233b. The first group of connection conductor structures 230a may include components different from the second group of connection conductor structures 230b. For example, the first group of connection conductor structures 230a may further include an upper connection solder 235, differently from the second group of the second group of connection conductor structures 230b.

The connection pad 231 may be disposed in the encapsulant 220, for example in a lower portion of the encapsulant 220. A lower surface of the connection pad 231 may be coplanar with a lower surface of the encapsulant 220 and may be in contact with a lower connection solder 233. In some implementations, the connection pad 231 may have a circular or polygonal plane shape. An upper surface of the first group of the connection pad 231a may be in contact with the upper connection solder 235 and may be electrically connected to the bridge die 250 through the upper connection solder 235. In some implementations, the first group of the connection pad 231a may have a bar shape extending in a horizontal direction, but example implementations thereof are not limited thereto. An upper surface of the second group of the connection pad 231b may be in contact with and electrically connected to the connection post 210. In some implementations, a first width W1 of the first group of the connection pad 231a in the horizontal direction may be smaller than a second width W2 of the second group of the connection pad 231b in the horizontal direction. When a plane shape of the first group of the connection pad 231a is a circular or a polygonal shape, the first width W1 may be defined as a maximum width in the horizontal direction (e.g., the X-direction or the Y-direction), and when the first group of the connection pad 231a is a bar shape extending in the horizontal direction, the first width W1 may be defined as a width in the short axis direction. When a plane shape of the second group of the connection pad 231b is a circular or a polygonal shape, the second width W2 may be defined as a maximum width in the horizontal direction (e.g., the X-direction or the Y-direction). The connection pads 231 may include a conductive material, for example, a metal including aluminum (Al), silver (Ag), tin (Sn), gold (Au), nickel (Ni), lead (Pb), titanium (Ti), or an alloy thereof.

The lower connection solder 233 may be disposed below a lower surface of the encapsulant 220, particularly below a lower surface of the connection pad 231. The lower connection solder 233 may be in contact with and electrically connected to the upper package pad 120 of the package substrate 100. The lower connection solder 233 may include a conductive material, for example, tin (Sn), bismuth (Bi), lead (Pb), silver (Ag), or an alloy thereof.

The upper connection solder 235 may be included in the first group of connection conductor structure 230a, and the second group of connection conductor structures 230b may not include the upper connection solder 235. The upper connection solder 235 may be in contact with and electrically connected to the lower bridge pad 265 of the bridge die 250. The upper connection solder 235 may be disposed on the first group of the connection pad 231 and may be buried in the encapsulant 220. The upper connection solder 235 may be in contact with the encapsulant 220. The upper connection solder 235 may include a conductive material, for example, tin (Sn), bismuth (Bi), lead (Pb), silver (Ag), or an alloy thereof.

The redistribution structure 280 may be disposed on the encapsulant 220 and may include an upper insulating layer 281 and redistribution patterns 282, 283, and 285. The redistribution patterns 282, 283, and 285 may include redistribution layers 282, redistribution vias 283, and upper pads 285.

The upper insulating layer 281 may cover an upper surface of the encapsulant 220. The upper insulating layer 281 may cover upper surfaces of the connection posts 210 and upper surfaces of the upper bridge pads 275. The upper surface of the upper insulating layer 281 may be defined as an upper surface of the interposer substrate 200. The upper insulating layer 281 may include a plurality of insulating layers. The upper insulating layer 281 may include an insulating material electrically and physically protecting the redistribution patterns 282, 283, and 285. For example, the upper insulating layer 281 may include a thermosetting resin such as an epoxy resin, a thermoplastic resin such as a polyimide, or a prepreg including inorganic fillers and/or glass fibers (glass fiber, glass cloth, glass fabric), Ajinomoto build-up film (ABF), frame retardant 4 (FR4), or the like.

The redistribution layers 282 may be disposed in the upper insulating layer 281. The number of the redistribution layers 282 may be greater or less than the example illustrated in the drawing. The redistribution layers 282 may be disposed in more or fewer layers than the example illustrated in the drawing. The redistribution layers 282 may include a conductive material, for example, a metal including copper (Cu), aluminum (Al), silver (Ag), tin (Sn), gold (Au), nickel (Ni), lead (Pb), titanium (Ti), or an alloy thereof.

The redistribution vias 283 may extend into a partial region of the upper insulating layer 281 and may be electrically connected to the redistribution layers 282. For example, the redistribution vias 283 may interconnect the redistribution layers 282 disposed at different levels. A portion of the redistribution vias 283 may interconnect the upper pads 285 to the redistribution layers 282. A portion of the redistribution vias 283 may interconnect the redistribution layers 282 to bridge upper pads 275. A portion of the redistribution vias 283 may interconnect the redistribution layers 282 to the connection posts 210. The redistribution vias 273 may include a conductive material, for example, a metal including copper (Cu), aluminum (Al), silver (Ag), tin (Sn), gold (Au), nickel (Ni), lead (Pb), titanium (Ti), or an alloy thereof. The redistribution vias 283 may be filled vias in which the metal material is filled in the via hole or conformal vias in which the metal material extends along the inner wall of the via hole.

The upper pads 285 may be disposed on the upper insulating layer 281. The upper surface of the upper pads 285 may be connected to and in contact with the semiconductor chips 300. The upper pads 285 may include a conductive material, for example, a metal including copper (Cu), aluminum (Al), silver (Ag), tin (Sn), gold (Au), nickel (Ni), lead (Pb), titanium (Ti), or an alloy thereof.

The semiconductor chips 300 may be disposed on the interposer substrate 200. The semiconductor chips 300 may be electrically connected to the package substrate 100 through the interposer substrate 200. Each of the semiconductor chips 300 may include a logic circuit such as a central processor (CPU), a graphics processor (GPU), a filled programmable gate array (FPGA), an application processor (AP), a digital signal processor, a cryptographic processor, a microprocessor, a microcontroller, an analog-to-digital converter, an application-specific IC (ASIC), or a memory circuit such as a volatile memory such as a dynamic RAM (DRAM) and static RAM (SRAM), and nonvolatile memory such as a phase change RAM (PRAM), magnetic RAM (MRAM), resistive RAM (RRAM), and flash memory.

The semiconductor chips 300 may include a first semiconductor chip 300A and a second semiconductor chip 300b disposed side by side on the interposer substrate 200. In some example implementations, the semiconductor chips 300 may include chips stacked vertically on the interposer substrate 200. The first semiconductor chip 300A and the second semiconductor chip 300b may include different types of semiconductor chips, but example implementations thereof is not limited thereto. For example, the first semiconductor chip 300A may include a logic chip, and the second semiconductor chip 300b may include a memory chip. In this case, the second semiconductor chip 300b may be provided as a high-capacity memory device such as a high bandwidth memory (HBM). The number of the semiconductor chips 300 may be greater than the example illustrated in the drawing (see FIG. 7). In some implementations, the mold layer covering the semiconductor chips 300 may be further disposed.

In the description below, the descriptions overlapping the description described with reference to FIGS. 1-3 will not be provided.

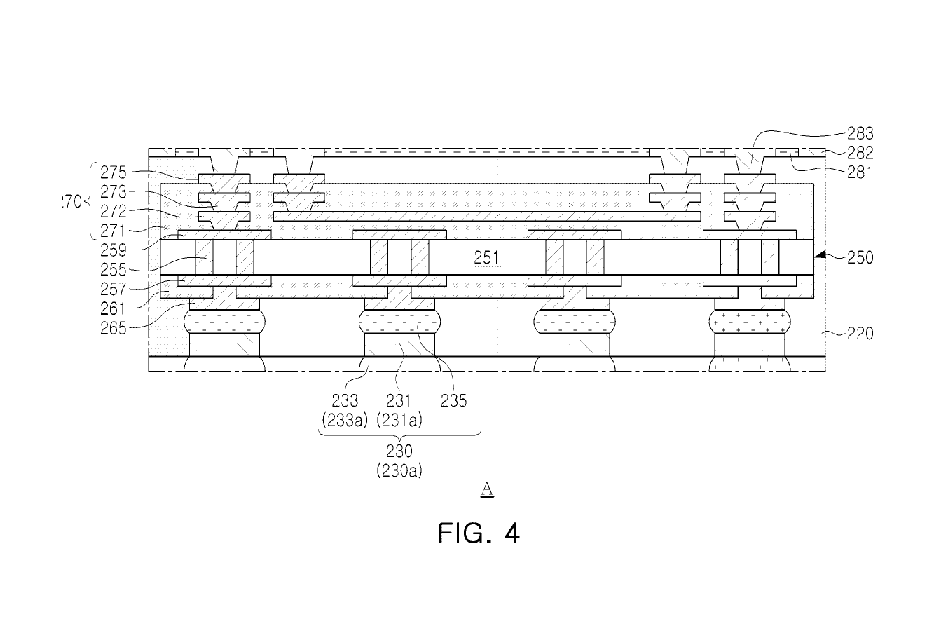

FIG. 4 is an enlarged diagram illustrating a portion of a semiconductor package according to example implementations, illustrating region ‘A’ in FIG. 2, and an example implementation different from the example implementation in FIG. 2.

Referring to FIG. 4 together with FIG. 2, differently from the example implementation in FIG. 3, upper surfaces of the upper bridge pads 275 may be spaced apart from the upper insulating layer 281. A portion of the redistribution vias 283 of the redistribution structure 280 may extend into the encapsulant 220 and may be in contact with the upper surface of the upper bridge pads 275. In this case, the upper surface of the upper bridge pads 275 may be protected in a process of removing a portion of the encapsulant 220 from an upper portion to form the redistribution structure 280 on the encapsulant 220.

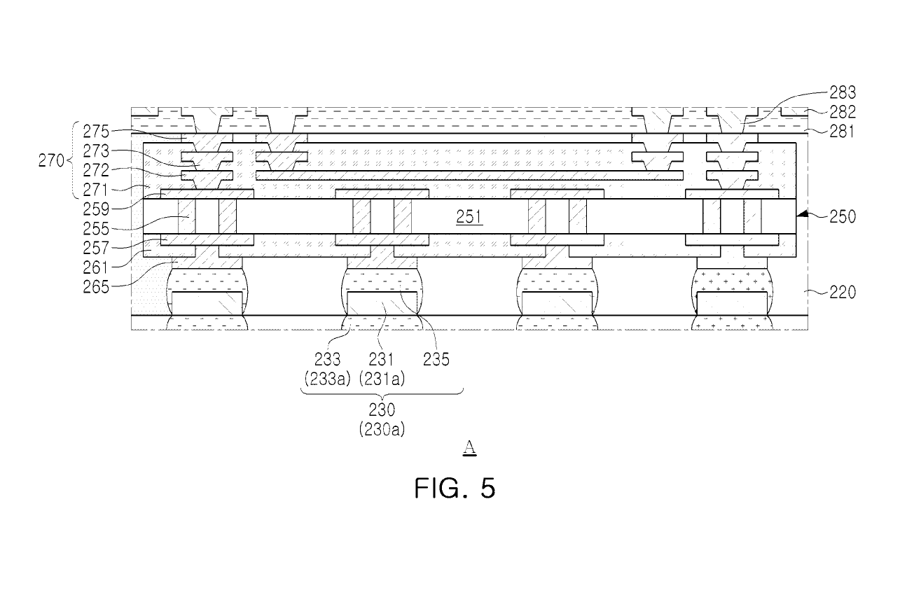

FIG. 5 is an enlarged diagram illustrating a portion of a semiconductor package according to example implementations, illustrating region ‘A’ in FIG. 2, and an example implementation different from the example implementation in FIG. 2.

Referring to FIG. 5 together with FIG. 2, differently from the example embodiment in FIG. 3, an upper connection solder 235 of the first group of connection conductor structures 230a may cover at least a portion of a side surface of the first group of the connection pad 231a. When a horizontal width of the first group of the connection pad 231a is formed relatively small, or when the first group of the connection pad 231a has a bar shape extending in the horizontal direction, the upper connection solder 235 may cover the upper surface of the first group of the connection pad 231a and also a side surface. In some implementations, when a misalignment occurs when the bridge die 250 including the upper connection solder 235 is mounted on a first group of the connection pad 231a, the upper connection solder 235 may cover at least a portion of a side surface of the first group of the connection pad 231a. In some implementations, the upper connection solder 235 may be in contact with a first group of the lower connection solder 233a. Depending on the size and the shape of the first group of the connection pad 231a, the form of contact between the upper connection solder 235 and the first group of the connection pad 231a may be varied.

The shape of an upper partial region of the bridge die 250 illustrated in FIG. 4 and the first group of connection conductor structures 230a illustrated in FIG. 5 may be compatible, and may thus be combined in various manners in example implementations.

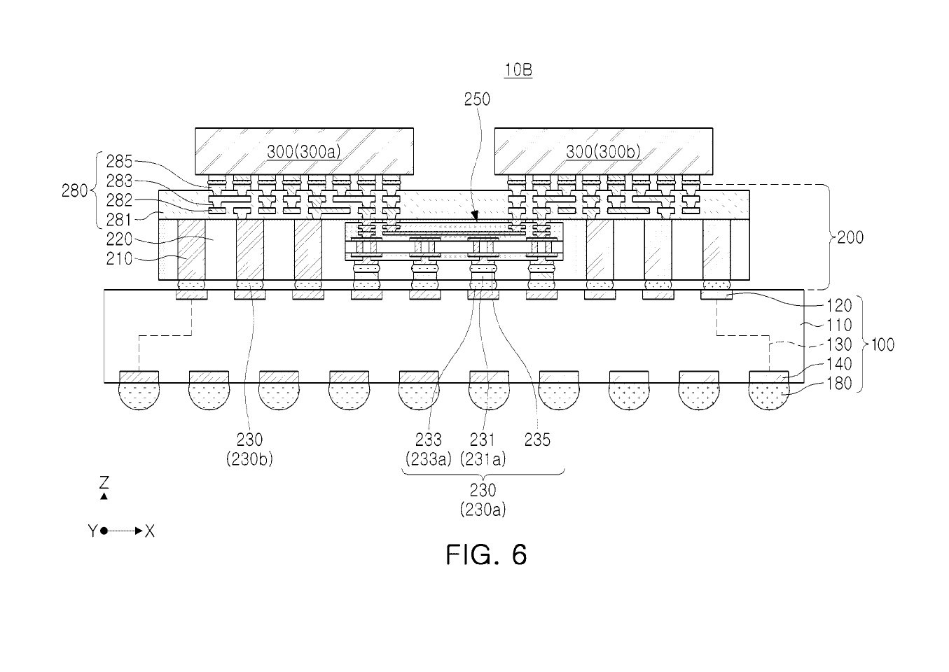

FIG. 6 is a cross-sectional diagram illustrating a semiconductor package according to example implementations, illustrating a region corresponding to FIG. 2.

Referring to FIG. 6 together with FIG. 2, a semiconductor package 10b may not include connection pads 231b in a second group of connection conductor structures 230b, differently from the semiconductor package 10A in FIG. 2. The second group of connection conductor structures 230b may only include a lower connection solder 233b. Accordingly, the connection posts 210 may be in contact with the second group of the lower connection solders 233b. Since the connection pads 231a of a first group of connection conductor structures 230a may be used for mounting the bridge die 250, the connection pads 231a and the upper connection solder 235 may be included as are in the example implementations.

FIG. 7 is a plan diagram illustrating a semiconductor package according to example implementations. For ease of description, only a portion of elements of the semiconductor package is illustrated in FIG. 7, and a region corresponding to FIG. 1 is illustrated.

Referring to FIG. 7, semiconductor chips 300 of semiconductor package 10C may be electrically connected to a first semiconductor chip 300A and a plurality of second semiconductor chips 300b. The first semiconductor chip 300A may be electrically connected to a plurality of second semiconductor chips 300b through a plurality of bridge dies 250, and the first semiconductor chip 300A and the plurality of second semiconductor chips 300b may transfer complex signal lines to each other through the plurality of bridge dies 250. In some implementations, the first semiconductor chip 300A may include a logic chip, and the second semiconductor chip 300b may include a memory chip. In this case, the second semiconductor chip 300b may be provided as a high-capacity memory device such as a high bandwidth memory (HBM). In some implementations, four second semiconductor chips 300b including a memory chip may be disposed around one first semiconductor chip 300A including a logic chip, but example implementations thereof are not limited thereto. For example, two second semiconductor chips 300b may be disposed around one first semiconductor chip 300A. In some implementations, the first semiconductor chip 300A and the second semiconductor chip 300b may have different sizes. For example, the first semiconductor chip 300A may have a size greater than a size of the second semiconductor chip 300b. The semiconductor package 10C may be configured in relation to the package substrate 100, the interposer substrate 200 including the bridge die 250, and the semiconductor chips 300 described with reference to FIGS. 1-6 in a compatible range.

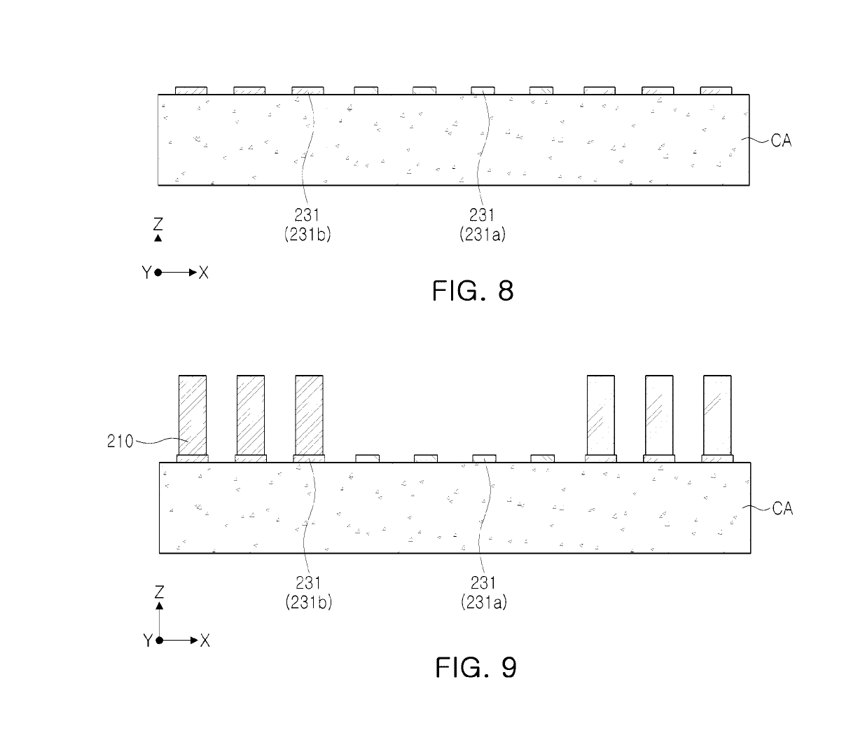

FIGS. 8-14 are cross-sectional diagrams illustrating processes of a method of manufacturing a semiconductor package in order according to example implementations, illustrating regions corresponding to FIG. 2.

Referring to FIG. 8, connection pads 231 may be formed on a carrier CA.

For example, as for the carrier CA, a polymer layer including a curable resin and a metal layer including nickel (Ni), titanium (Ti), or the like, may be sequentially coated on a copper clad laminate (CCL). The connection pads 231 may be formed by a method such as patterning a metal material on the carrier CA using a plating process on the carrier CA. The connection pads 231 may form a first group of connection pads 231a and a second group of connection pads 231b. In an example implementation, the first group of the connection pads 231a may be formed to have a plane shape or a width different from those of the second group of the second group of the connection pads 231b. In an example implementation, the first group of the connection pads 231a may be formed to have a width smaller than a width of the second group of the connection pads 231b. In some implementations, the second group of the connection pads 231b may not be formed, and in this case, the semiconductor package 10b in FIG. 6 may be manufactured by a subsequent process.

Referring to FIG. 9, connection posts 210 may be formed on the second group of the connection pads 231b.

The connection posts 210 may be formed on the second group of the connection pads 231b by a plating process such as electrolytic plating or electroless plating. The connection posts 210 may be formed by forming a photoresist pattern exposing a region in which the connection posts 210 are to be formed, and forming a conductive material on the exposed region. In some implementations, the connection posts 210 may include a metal such as copper (Cu), and a metal seed layer (not illustrated) including titanium (Ti), copper (Cu), or the like, may be formed on the lower surface. In some implementations, when the second group of the connection pads 231b are not formed, the connection posts 210 may be formed on the carrier CA in the region in which the connection posts 210 of the semiconductor package 10b in FIG. 6 are to be formed.

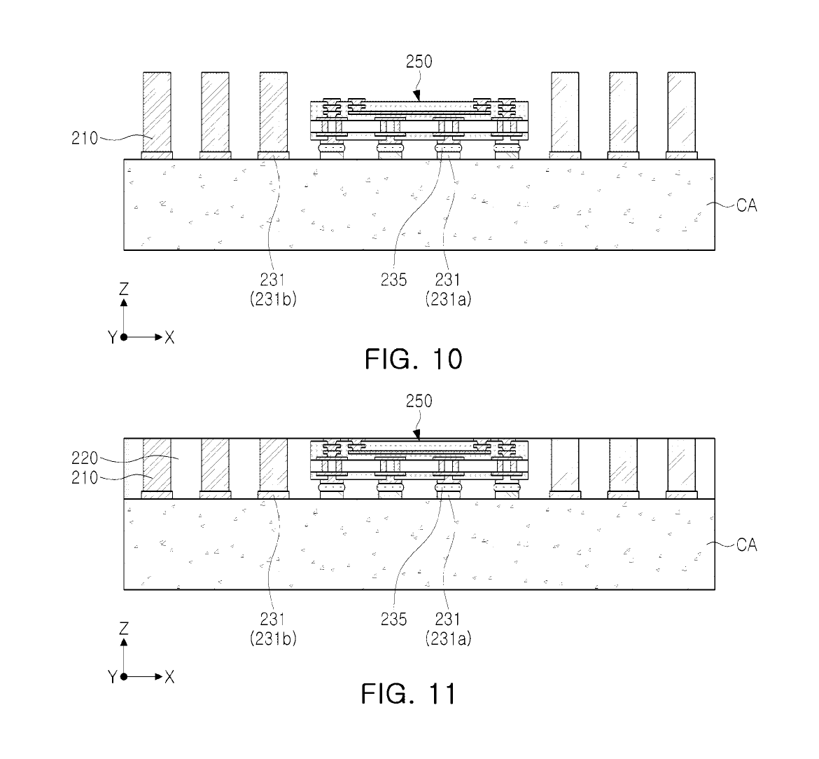

Referring to FIG. 10, the bridge die 250 may be mounted on the first group of the connection pads 231a.

Upper connection solders 235 may be disposed on a lower surface of the bridge die 250, and in the bridge die 250, the upper connection solders 235 may be disposed and mounted on the first of the connection pads 231a. An upper end of the bridge die 250 may be positioned at a level lower than a level of an upper end of the connection posts 210. In the manufacturing method, by forming the connection posts 210 preferentially and mounting the bridge die 250, the bridge die 250 may be prevented from receiving stress from the photoresist pattern for forming the connection posts 210.

Referring to FIG. 11, an encapsulant 220 surrounding a bridge die 250 and connection posts 210 may be formed.

The encapsulant 220 may surround the bridge die 250 and the connection posts 210, may be formed to cover an upper surface of the connection posts 210, and a portion thereof may be removed from an upper portion. The connection posts 210 may be partially removed from an upper portion. The upper surfaces of an upper bridge pads 275 (see FIG. 3) of the bridge die 250 may be covered by an encapsulant 220, and may be exposed by removing the encapsulant 220 from an upper portion. Accordingly, the upper surface of the encapsulant 220, which is the upper surface of the connection posts 210, and the upper surface of the upper bridge pads 275, which are an upper end of the bridge die 250, may be positioned at the same level and may be coplanar with each other. In some implementations, when the process of removing a portion of the encapsulant 220 and the connection posts 210 from an upper portion is performed at a level higher than a level of the upper bridge pads 275, which are an upper end of the bridge die 250, the upper surfaces of the upper bridge pads 275, which are an upper end of the bridge die 250, may be covered by the encapsulant 220, and example implementations in FIG. 4 may be manufactured according to a subsequent process.

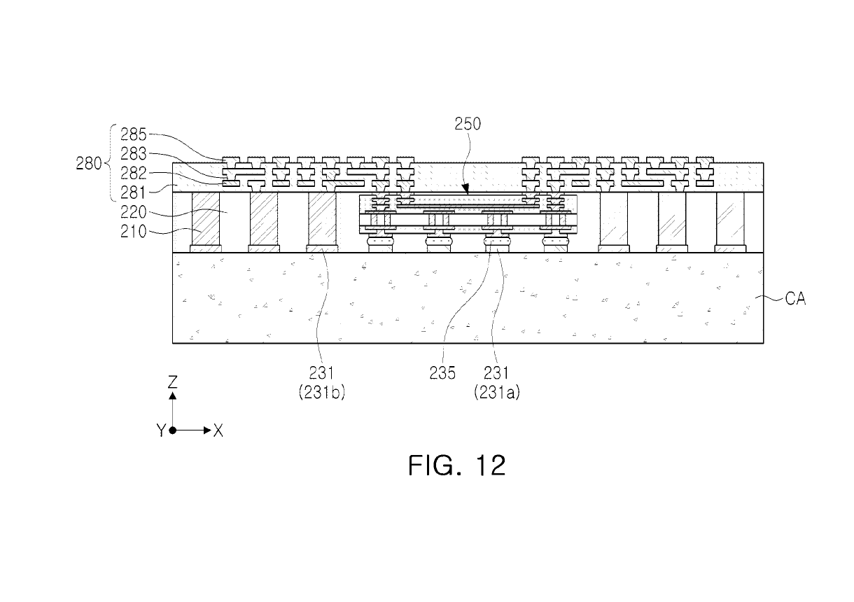

Referring to FIG. 12, a redistribution structure 280 may be formed on the encapsulant 220.

A redistribution structure 280 including an upper insulating layer 281, redistribution layers 282, redistribution vias 283, and upper pads 285 may be formed on the encapsulant 220. The upper insulating layer 281 may be formed by sequentially applying and curing a photosensitive material, for example, PID. The redistribution patterns 282, 283, and 285 may be formed by forming a via hole penetrating the upper insulating layer 281 and performing an exposure process and a development process, and patterning a metal material on the upper insulating layer 281 using a plating process.

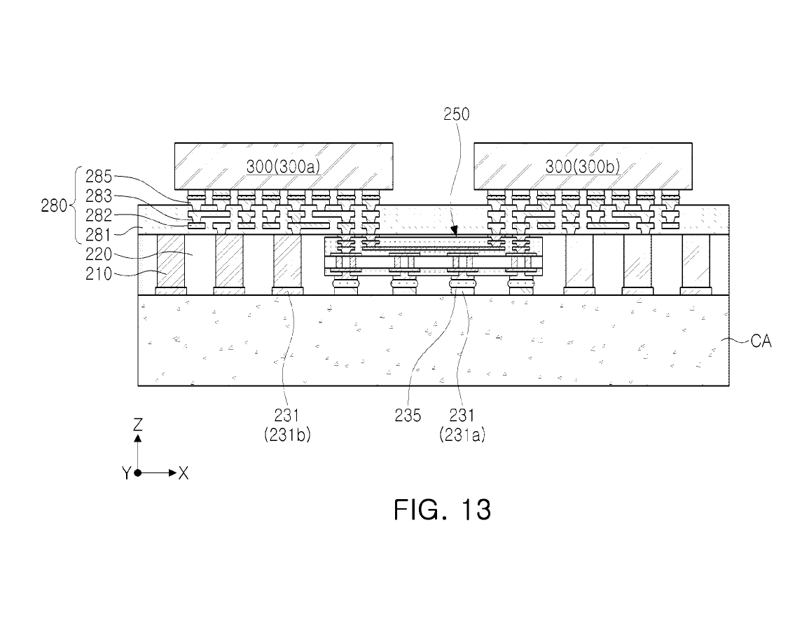

Referring to FIG. 13, the semiconductor chips 300 may be mounted on the redistribution structure 280.

The semiconductor chips 300 may be mounted, for example, in a flip-chip manner. The semiconductor chips 300 may be connected to the upper pads 285 through the connection bumps included in each chip. The mounted semiconductor chips 300 may be electrically connected to the bridge die 250 and the connection posts 210 through the redistribution structure 280, and may be electrically connected to the package substrate 100 through the connection conductor structures 230.

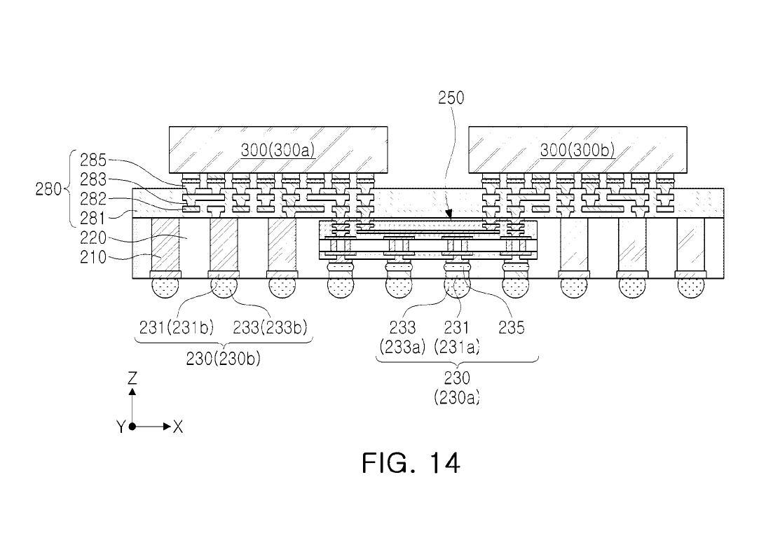

Referring to FIG. 14, the carrier CA may be removed and the lower connection solders 233 may be formed.

The lower connection solders 233 may be formed below the connection pads 231. The lower connection solders 233 may include the first group of the lower connection solders 233a and the second group of the lower connection solders 233b. In this process, the first group of connection conductor structures 230A, a first group of the lower connection solder 233a, and the first group of connection conductor structures 230A including an upper connection solder 235 may be formed, and a second group of the connection pad 231b, and the second group of connection conductor structures 230b including a second group of the lower connection solder 233b may be formed. The first group of connection conductor structures 230A may further include upper connection solders 235, differently from the second group of connection conductor structures 230b. In some implementations, by including the first group of connection conductor structures 230A disposed in a lower portion of the encapsulant 220, exposing of the bridge die 250 to a lower end of the encapsulant 220 in the process after the carrier CA is removed may be reduced or prevented, and accordingly, process stability may be ensured. Thereafter, referring to FIG. 2 together, the structure in FIG. 14 may be mounted on the package substrate 100, and the semiconductor package 10A in FIG. 2 may be manufactured.

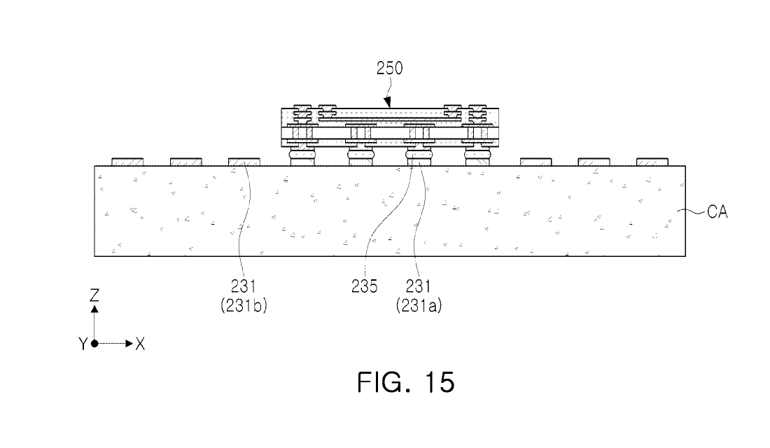

FIG. 15 is a cross-sectional diagram illustrating a method of manufacturing a semiconductor package according to example implementations, illustrating a region corresponding to FIG. 2 and the processes after FIG. 8.

Referring to FIG. 15, differently from the manufacturing method in FIG. 9, the bridge die 250 may be mounted preferentially before forming the connection posts 210.

The order in which the bridge die 250 and the connection posts 210 are formed may be varied depending on the manufacturing method in example implementations. If desired, depending on the manufacturing method, the bridge die 250 may be mounted preferentially on the first group of the connection pads 231a, and the connection posts 210 may be formed on the second group of the connection pads 231b in a subsequent process. After forming the bridge die 250 and the connection posts 210, the processes the same as the processes subsequent to FIG. 11 may be performed.

According to the aforementioned example implementations, by not providing a lower redistribution structure of the interposer substrate including the bridge die connecting the individual chips to each other, a semiconductor package having improved integration density and electrical properties may be provided.

Also, by not providing a lower redistribution structure of an interposer substrate including a bridge die connecting individual chips to each other, the process may be simplified, and by including connection conductor structures, a method of manufacturing a semiconductor package of which process stability is improved may be provided.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

According to example implementations of the present disclosure, a method of manufacturing a semiconductor package includes forming connection pads on a carrier, wherein the connection pads include a first group of the connection pads and a second group of the connection pads of; forming connection posts on the second group of the connection pads; mounting a bridge die including upper connection solders formed on a lower surface thereof on the first group of connection pads, wherein the upper connection solders are disposed between the bridge die and the first group of the connection pads; forming an encapsulant surrounding the bridge die and the connection posts; forming a redistribution structure on the encapsulant; mounting semiconductor chips on the redistribution structure; removing the carrier; forming a lower connection solder on a lower surface of each of the connection pads.

While the example implementations have been illustrated and described above, it will be configured as apparent to those skilled in the art that modifications and variations could be made without departing from the scope of the present disclosure as defined by the appended claims.

What is claimed is:

1. A semiconductor package, comprising:
a bridge die;
an encapsulant that surrounds the bridge die;
a redistribution structure on the encapsulant and comprising redistribution patterns electrically connected to the bridge die and an upper insulating layer surrounding the redistribution patterns;
semiconductor chips on the redistribution structure and electrically connected to the redistribution patterns;
connection posts that extend in a vertical direction in the encapsulant and electrically connected to the redistribution patterns; and
a plurality of connection conductor structures below the bridge die and the connection posts,
wherein the plurality of connection conductor structures comprise a first group of the plurality of connection conductor structures that overlap the bridge die, and a second group of the plurality of connection conductor structures that overlap the connection posts, and
wherein each connection conductor structure of the first group of the plurality of connection conductor structures comprises:
a connection pad;
an upper connection solder in contact with and electrically connected to the bridge die on the connection pad; and
a lower connection solder below the connection pad.

2. The semiconductor package of claim 1, wherein the upper connection solder of each connection conductor structure of the first group of the plurality of connection conductor structures is within the encapsulant, and the lower connection solder is below a lower surface of the encapsulant.

3. The semiconductor package of claim 1, wherein each connection conductor structure of the second group of the plurality of connection conductor structures comprises:
a connection pad in contact with and electrically connected to the connection post; and
a lower connection solder below the connection pad.

4. The semiconductor package of claim 3, wherein a first width of the connection pad of each of the first group of the plurality of the connection conductor structures is smaller than a second width of the connection pad of each connection conductor structure of the second group of the plurality of the connection conductor structures.

5. The semiconductor package of claim 1, wherein the bridge die comprises:
a bridge body;
a bridge redistribution structure on the bridge body, the bridge redistribution structure comprising (i) bridge redistribution patterns electrically connected to the redistribution patterns and (ii) an upper bridge insulating layer that surrounds the bridge redistribution patterns;
lower bridge pads below the bridge body; and
through-vias that extend into the bridge body and electrically connect the bridge redistribution patterns to the lower bridge pads.

6. The semiconductor package of claim 5, wherein the upper connection solder of the first group of the plurality of connection conductor structures is in contact with the lower bridge pads of the bridge die.

7. The semiconductor package of claim 5, wherein the upper bridge insulating layer is spaced apart from the upper insulating layer.

8. The semiconductor package of claim 5, wherein the upper connection solder is in contact with the encapsulant.

9. The semiconductor package of claim 1, wherein, in each connection conductor structure of the first group of the plurality of connection conductor structures, the upper connection solder covers at least a portion of a side surface of the connection pad.

10. The semiconductor package of claim 1, wherein an upper end of the bridge die is at a same level as upper surfaces of the connection posts, and a lower end of the bridge die is at a level higher than a level of lower surfaces of the connection posts.

11. The semiconductor package of claim 1, wherein at least one of the first group of the plurality of connection conductor structures overlaps the semiconductor chips in a vertical direction.

12. A semiconductor package, comprising:
a bridge die comprising a bridge body, through-vias that extend into the bridge body, a bridge redistribution structure on the bridge body, a lower bridge insulating layer that covers a lower surface of the bridge body, and lower bridge pads below the lower bridge insulating layer and electrically connected to the through-vias;
an encapsulant that surrounds the bridge die;
a redistribution structure on the encapsulant and including an upper insulating layer and redistribution patterns in the upper insulating layer; and
connection conductor structures electrically connected to the lower bridge pads below the bridge die,
wherein the bridge redistribution structure comprises:
an upper bridge insulating layer;
upper bridge pads on the upper bridge insulating layer and electrically connected to the redistribution patterns; and
bridge redistribution layers that electrically connect the through-vias to the upper bridge pads in the upper bridge insulating layer,
wherein the encapsulant covers at least a portion of each of an upper surface of the upper bridge insulating layer, a lower surface of the lower bridge insulating layer, side surfaces of the upper bridge pads and side surfaces of the lower bridge pads.

13. The semiconductor package of claim 12, wherein the encapsulant is in contact with at least a portion of each of an upper surface of the upper bridge insulating layer, a lower surface of the lower bridge insulating layer, side surfaces of the upper bridge pads and side surfaces of the lower bridge pads.

14. The semiconductor package of claim 12, wherein upper surfaces of the upper bridge pads are in contact with the upper insulating layer.

15. The semiconductor package of claim 12, wherein the bridge die comprises:
an upper body pad in contact with an upper surface of the bridge body and upper surfaces of the through-vias, wherein the upper body pad electrically connects the through-vias and the bridge redistribution layers; and
a lower body pad in contact with a lower surface of the bridge body and lower surfaces of the through-vias, wherein the lower body pad electrically connects the through-vias and the lower bridge pads.

16. The semiconductor package of claim 12,
wherein the bridge body comprises silicone, and
wherein the encapsulant comprises a material different from a material of the bridge body.

17. A semiconductor package, comprising:
an encapsulant;
a redistribution structure on the encapsulant, wherein the redistribution structure comprises an upper insulating layer and redistribution patterns in the upper insulating layer;
semiconductor chips on the redistribution structure, and electrically connected to the redistribution patterns;
a bridge die in the encapsulant, and electrically connected to the semiconductor chips through the redistribution patterns;
connection posts spaced apart from the bridge die in a horizontal direction in the encapsulant, wherein the connection posts extend in a vertical direction and are electrically connected to the redistribution patterns;
a first group of connection pads electrically connected to the bridge die below the bridge die; and
a first group of lower connection solders below lower surfaces of the first group of connection pads,
wherein the lower surfaces of the first group of connection pads are coplanar with a lower surface of the encapsulant.

18. The semiconductor package of claim 17, comprising:
a second group of connection pads electrically connected to the connection posts below the connection posts; and
a second group of lower connection solders below lower surfaces of the second group of the connection pads,
wherein the lower surfaces of the second group of connection pads are coplanar with a lower surface of the encapsulant.

19. The semiconductor package of claim 17, comprising:
a second group of lower connection solders electrically connected to the connection posts below the connection posts,
wherein lower surfaces of the connection posts are coplanar with the encapsulant.

20. The semiconductor package of claim 17,
wherein the semiconductor chips comprise a first semiconductor chip comprising a logic chip, and a second semiconductor chip comprising a memory chip,
wherein the first semiconductor chip and the second semiconductor chip are spaced apart from each other in the horizontal direction, and
wherein the bridge die comprises a portion overlapping the first semiconductor chip and a portion overlapping the second semiconductor chip.
